(19) United States
(12) Patent Application Publication
(10) Pub. No.: US 2025/0081811 A1
(43) Pub. Date: Mar. 6, 2025

(54) DISPLAY PANEL, MANUFACTURING METHOD THEREFOR, AND DISPLAY APPARATUS

(71) Applicants: CHENGDU BOE OPTOELECTRONICS TECHNOLOGY CO., LTD., Chengdu, Sichuan (CN); BOE TECHNOLOGY GROUP CO., LTD., Beijing (CN)

(72) Inventors: Xiangdan DONG, Beijing (CN); Ming HU, Beijing (CN); Cong FAN, Beijing (CN)

(21) Appl. No.: 18/293,194

(22) PCT Filed: Sep. 20, 2022
(86) PCT No.: PCT/CN2022/120042

§ 371 Date: Jan. 29, 2024

(30) Foreign Application Priority Data
Oct. 27, 2021 (CN) 202111257710.9

(51) Int. Cl. H10K 59/80; H10K 59/12; H10K 59/131; H10K 77/10; H10K 102/00

(52) U.S. Cl. CPC H10K 59/8723; H10K 59/1201; H10K 59/131; H10K 77/111; H10K 2102/311

(57) ABSTRACT

Embodiments of the present disclosure disclose a display panel, a manufacturing method therefor, and a display device. The display panel includes a base substrate, the display panel being provided with a through hole penetrating through the base substrate along a thickness direction of the base substrate, and the base substrate being provided with a display region and a through hole packaging region located between the display region and the through hole; a first source-drain metal layer located at a side of the base substrate; a second source-drain metal layer located at a side of the first source-drain metal layer away from the base substrate; at least one spacer located at a side of the base substrate, located in the through hole packaging region and arranged around the through hole. The at least one spacer is disposed in a different layer from the second source-drain metal layer.

### CROSS-REFERENCE TO RELATED APPLICATION

The present application claims priority to the Chinese Patent Application No. 202111257710.9 filed to China National Intellectual Property Administration on Oct. 27, 2021 and entitled “Display Panel, Manufacturing Method Therefor and Display Device”, the content of which is incorporated herein by reference in its entirety.

### TECHNICAL FIELD

The present disclosure relates to the technical field of display, and in particular to a display panel, a manufacturing method therefor and a display device.

### BACKGROUND

In the related art, a display panel of a bezel-less screen design is increasingly popular with consumers. A bezel-less screen refers to a panel structure using an ultra-narrow bezel design and with a notch in a display region for accommodating a camera and/or other devices. The bezel-less screen has the highest screen-to-body ratio among the panel display screens.

### SUMMARY

Embodiments of the present disclosure provide a display panel, a manufacturing method therefor, and a display device, which are used for solving major defective problems, such as severe corrosion and formation of bubbles on the spacer around the camera hole region of a bezel-less screen, etc.

Embodiments of the present disclosure provides a display panel, including:
a base substrate, the display panel being provided with a through hole penetrating through the base substrate along a thickness direction of the base substrate, and the base substrate being provided with a display region and a through hole packaging region located between the display region and the through hole;
a first source-drain metal layer, located at a side of the base substrate;
a second source-drain metal layer, located at a side of the first source-drain metal layer away from the base substrate;
at least one spacer, located at a side of the base substrate, located in the through

hole packaging region and arranged around the through hole; the at least one spacer being disposed in a different layer from the second source-drain metal layer.

Optionally, in the display panel as mentioned above provided by embodiments of the present disclosure, the at least one spacer is disposed in the same layer and made of the same material as the first source-drain metal layer.

Optionally, in the display panel as mentioned above provided by embodiments of the present disclosure, the display panel further includes: at least one transparent wiring layer located at a side of the second source-drain metal layer away from the base substrate, and an anode located at a side of the at least one transparent wiring layer away from the base substrate; an orthographic projection of the at least one transparent wiring layer on the base substrate does not overlap with an orthographic projection of the at least one spacer on the base substrate, and an orthographic projection of the anode on the base substrate does not overlap with the orthographic projection of the at least one spacer on the base substrate.

Optionally, in the display panel as mentioned above provided by embodiments of the present disclosure, the display panel further includes: a first passivation layer located between the second source-drain metal layer and the first source-drain metal layer, and a first planarization layer between the first passivation layer and the second source-drain metal layer; an orthographic projection of the first planarization layer on the base substrate does not overlap with the orthographic projection of the at least one spacer on the base substrate, the first passivation layer covers the through hole packaging region, and an orthographic projection of the first passivation layer on the base substrate does not overlap with the orthographic projection of the at least one spacer on the base substrate.

Optionally, in the display panel as mentioned above provided by embodiments of the present disclosure, the display panel further includes: a second passivation layer located between the at least one transparent wiring layer and the anode, an orthographic projection of the second passivation layer on the base substrate does not overlap with the orthographic projection of the at least one spacer on the base substrate.

Optionally, in the display panel as mentioned above provided by embodiments of the present disclosure, the display panel further includes: at least one transparent wiring layer located at a side of the second source-drain metal layer away from the base substrate, an anode located at a side of the at least one transparent wiring layer away from the base substrate, and a first film layer located between the at least one transparent wiring layer and the anode; an orthographic projection of the at least one transparent wiring layer on the base substrate does not overlap with an orthographic projection of the at least one spacer on the base substrate, and an orthographic projection of the anode on the base substrate does not overlap with the orthographic projection of the at least one spacer on the base substrate;
the at least one spacer is disposed in the same layer and made of the same material as the first film layer.

Optionally, in the display panel as mentioned above provided by embodiments of the present disclosure, a material of the first film layer is the same as a material of the first source-drain metal layer, or a material of the first film layer is negative photoresist.

Optionally, in the display panel as mentioned above provided by embodiments of the present disclosure, the display panel further includes: at least one transparent wiring layer located at a side of the second source-drain metal layer away from the base substrate, an anode located at a side of the at least one transparent wiring layer away from the base substrate, a second planarization layer located between the at least one transparent wiring layer and the second source-drain metal layer, and a negative photoresist layer located between the second source-drain metal layer and the second planarization layer; an orthographic projection of the at least one transparent wiring layer on the base substrate does not overlap with an orthographic projection of the at least one spacer on the base substrate, and an orthographic projection of the anode on the base substrate does not overlap with the orthographic projection of the at least one spacer on the base substrate;
the at least one spacer is disposed in the same layer and made of the same material as the negative photoresist layer.

Optionally, in the display panel as mentioned above provided by embodiments of the present disclosure, the display panel further includes: a first planarization layer located between the first source-drain metal layer and the second source-drain metal layer.

Optionally, in the display panel as mentioned above provided by embodiments of the present disclosure, in a case where a material of the at least one spacer is negative photoresist, the display panel further includes a first passivation layer located between the first planarization layer and the first source-drain metal layer, the first passivation layer covers the through hole packaging region, and an orthographic projection of the first passivation layer on the base substrate does not overlap with the orthographic projection of the at least one spacer on the base substrate.

Optionally, in the display panel as mentioned above provided by embodiments of the present disclosure, the display panel further includes: a light-emitting layer located at a side of the anode away from the base substrate, a cathode located at a side of the light-emitting layer away from the base substrate, and an encapsulation layer located at a side of the cathode away from the base substrate; the light-emitting layer is disconnected at a position of the at least one spacer;
the encapsulation layer includes a first inorganic layer, an organic layer and a second inorganic layer which are stacked, an orthographic projection of each of the first inorganic layer, the organic layer and the second inorganic layer on the base substrate covers the display region and the through hole packaging region.

Correspondingly, embodiments of the present disclosure also provides a display device, which includes the display panel as mentioned above.

Correspondingly, embodiments of the present disclosure also provides a manufacturing method for manufacturing the display panel according to any embodiment as mentioned above, which includes:
providing a base substrate, the base substrate being provided with a display region, a through hole region, and a through hole packaging region located between the display region and the through hole region;
forming a first source-drain metal layer at a side of the base substrate;
forming a second source-drain metal layer at a side of the first source-drain metal layer away from the base substrate;
forming at least one spacer at a side of the through hole packaging region of the base substrate and arranged around the through hole region, the at least one spacer being disposed in a different layer from the second source-drain metal layer;
cutting the through hole region to form a through hole.

Optionally, in the manufacturing method as mentioned above provided by embodiments of the present disclosure, the forming the at least one spacer at a side of the through hole packaging region of the base substrate and arranged around the through hole region, specifically includes:
forming the first source-drain metal layer in the display region and the at least one spacer in the through hole packaging region by one patterning process.

Optionally, in the manufacturing method as mentioned above provided by embodiments of the present disclosure, after forming the first source-drain metal layer and before forming the second source-drain metal layer, the manufacturing method further includes: forming a first passivation film layer and a first planarization film layer, and patterning the first planarization film layer to form a first planarization layer, an orthographic projection of the first planarization layer on the base substrate does not overlap with an orthographic projection of the at least one spacer on the base substrate;
after forming the second source-drain metal layer, the manufacturing method further includes:
forming at least one transparent wiring layer, wherein an orthographic projection of the at least one transparent wiring layer on the base substrate does not overlap with the orthographic projection of the at least one spacer on the base substrate;
forming a second passivation film layer at a side of the transparent wiring layer away from the base substrate;
patterning the first passivation film layer and the second passivation film layer by one patterning process, so as to form a first passivation layer and completely remove the second passivation film layer, wherein the first passivation layer covers the through hole packaging region, and an orthographic projection of the first passivation layer on the base substrate does not overlap with the orthographic projection of the at least one spacer on the base substrate; or, patterning the first passivation film layer and the second passivation film layer by one patterning process, so as to form a first passivation layer and a second passivation layer. The first passivation layer covers the through hole packaging region, an orthographic projection of the first passivation layer on the base substrate does not overlap with the orthographic projection of the at least one spacer on the base substrate, and an orthographic projection of the second passivation layer on the base substrate does not overlap with the orthographic projection of the at least one spacer on the base substrate.

Optionally, in the manufacturing method as mentioned above provided by embodiments of the present disclosure, after forming the first source-drain metal layer and before forming the second source-drain metal layer, the manufacturing method further includes: forming a first planarization layer, wherein an orthographic projection of the first planarization layer on the base substrate does not overlap with an orthographic projection of the at least one spacer on the base substrate;
after forming the second source-drain metal layer, the manufacturing method further includes: forming at least one transparent wiring layer, wherein an orthographic projection of the at least one transparent wiring layer on the base substrate does not overlap with the orthographic projection of the at least one spacer on the base substrate;
the forming the at least one spacer at a side of the through hole packaging region of the base substrate and arranged around the through hole region, specifically includes:
forming a first material film layer made of the same material as the first source-drain metal layer at a side of the at least one transparent wiring layer away from the base substrate;
patterning the first material film layer to form a first film layer located in the display region and the at least one spacer located in the through hole packaging region.

Optionally, in the manufacturing method as mentioned above provided by embodiments of the present disclosure, after forming the first source-drain metal layer and before forming the second source-drain metal layer, the manufacturing method further includes: forming a first passivation layer and a first planarization layer, wherein an orthographic projection of the first passivation layer on the base substrate does not overlap with an orthographic projection of the at least one spacer on the base substrate, and an orthographic projection of the first planarization layer on the base substrate does not overlap with the orthographic projection of the at least one spacer on the base substrate;
after forming the second source-drain metal layer, the manufacturing method further includes: forming at least one transparent wiring layer, wherein an orthographic projection of the at least one transparent wiring layer on the base substrate does not overlap with the orthographic projection of the at least one spacer on the base substrate;
the forming the at least one spacer at a side of the through hole packaging region of the base substrate and arranged around the through hole region, specifically includes:
forming a second material film layer made of negative photoresist at a side of the at least one transparent wiring layer away from the base substrate;
patterning the second material film layer to form a first film layer located in the display region and the at least one spacer located in the through hole packaging region.

### BRIEF DESCRIPTION OF DRAWINGS

FIG. 1 is a top view of a display panel;

FIG. 2 is an enlarged view of a through hole packaging region in FIG. 1;

FIG. 3 is a layout diagram along the DD′ direction in FIG. 2;

FIG. 4 is a schematic structural diagram of a display panel in the related art;

FIG. 5 is a schematic structural diagram of another display panel in the related art;

FIG. 6A is a schematic structural diagram of another display panel in the related art;

FIG. 6B is a schematic structural diagram of transparent wirings;

FIG. 7 is a schematic structural diagram of another display panel in the related art;

FIG. 8 is a schematic diagram of a bubble generated in the spacer region in the related art;

FIG. 9 is a schematic cross-sectional view of the display region in FIG. 1; and

FIGS. 10-19 are schematic structural diagrams of a display panel provided by the embodiment of the present disclosure.

### DETAILED DESCRIPTION

In order to make the purpose, technical scheme and advantages of the present disclosure more clear, specific implementations of the display panel, the manufacturing method thereof and the display device provided by the embodiments of the present disclosure will be described in detail with reference to the attached drawings. It should be understood that the preferred embodiments described below are only used to illustrate and explain the present disclosure, and are not used to limit the present disclosure. And the embodiments in the application and the features in the embodiments can be combined with each other without conflict.

The thickness, size and shape of each layer of thin film in the drawings do not reflect the true proportion of the display panel, and are only intended to schematically illustrate the present disclosure.

With the rapid development and application of active-matrix organic light-emitting diode (AMOLED), the display screens of the current flexible mobile phones, according to the special-shaped changes in the placement of the camera underneath them, can be divided into notch screens, AA hole digging screens/blind hole screens and the most popular under display camera (UDC) screens.

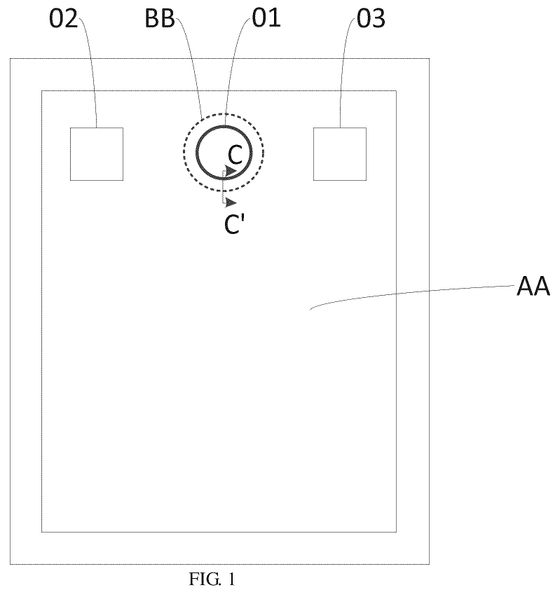

However, although the current under display camera is considered as the most advanced full-screen camera technology in the development of AMOLED technology, the development of this technology is still limited by the defects, such as low transmittance of the position of the camera hole, low life span of the light-emitting pixels, and poor photographic display effect. Therefore, a TOF face unlocking technology, which applies UDC technology to face unlocking, combined with AA hole technology used for camera photography, namely “under display TOF+AA hole” technology, is subsequently proposed. As shown in FIG. 1, a through hole 01 for the AA hole camera is set in the display region AA of the display panel, and a transmitting hole 02 and a receiving hole 03 for the under display TOF face unlocking are set on both sides of the through hole 01. The application of this technology integrates the most advanced under display camera technology and the most mature and widely used AA hole camera photography technology.

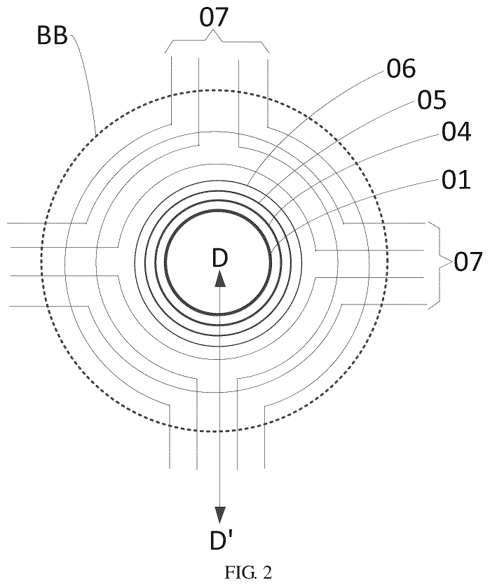

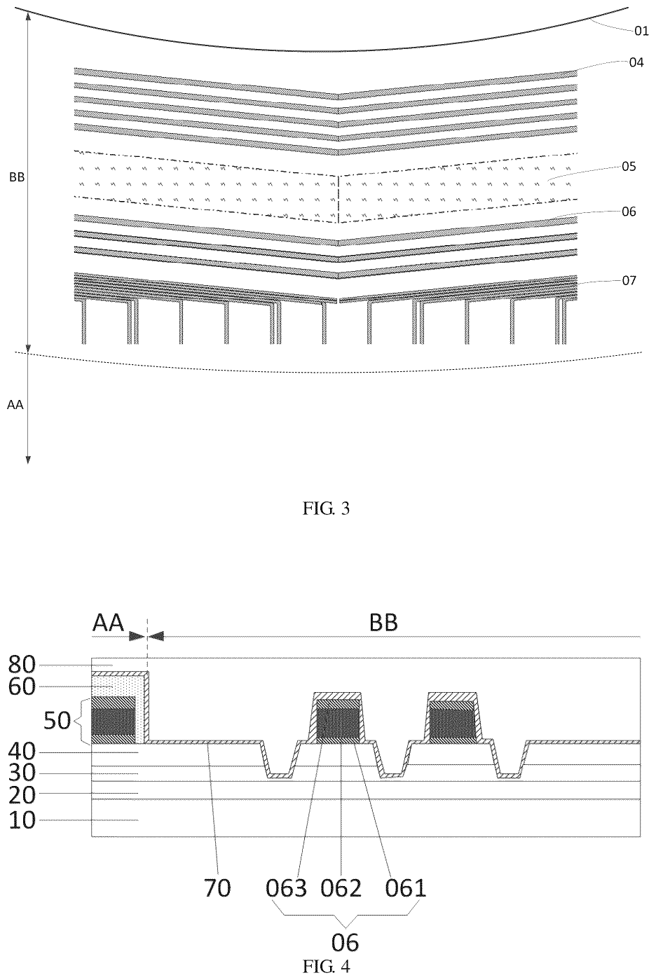

Specifically, as shown in FIG. 1, a through hole packaging region BB is provided between the display region AA and the through hole 01. As shown in FIGS. 2 and 3, FIG. 2 is an enlarged view of the through hole packaging region BB in FIG. 1, FIG. 3 is a layout diagram of the DD' direction in FIG. 2, and the through hole packaging region BB includes at least one crack dam 04 arranged around the through hole 01, and a dam 05 arranged around the crack dam 04, at least one spacer 06 arranged around the dam 05, and wires 07 disposed at the periphery of the spacer 06. The position of the through hole 01 is used to place the camera, the crack dam 04 is used to prevent the cracks generated when digging the through hole 01 from spreading to the display region AA, the dam 05 is used to prevent the organic layer in the encapsulation layer from flowing to the through hole 01, and the spacer 06 is used to isolate the light-emitting layer and prevent the water vapor at the through hole 01 from entering the display region AA. Because the through hole 01 is dug in the display region AA, the wires 07 (such as data lines) originally set at the position of the through hole 01 need to bypass the through hole 01.

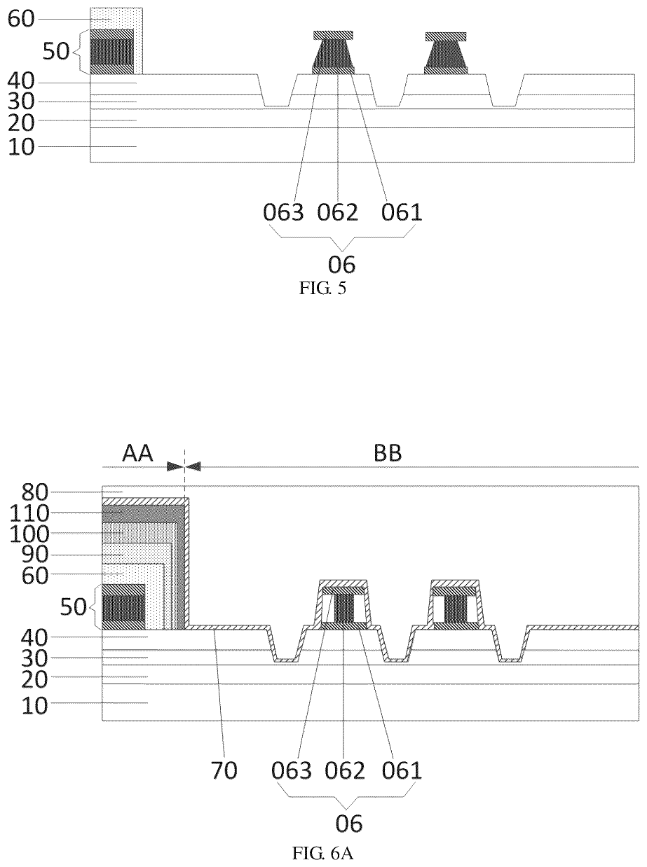

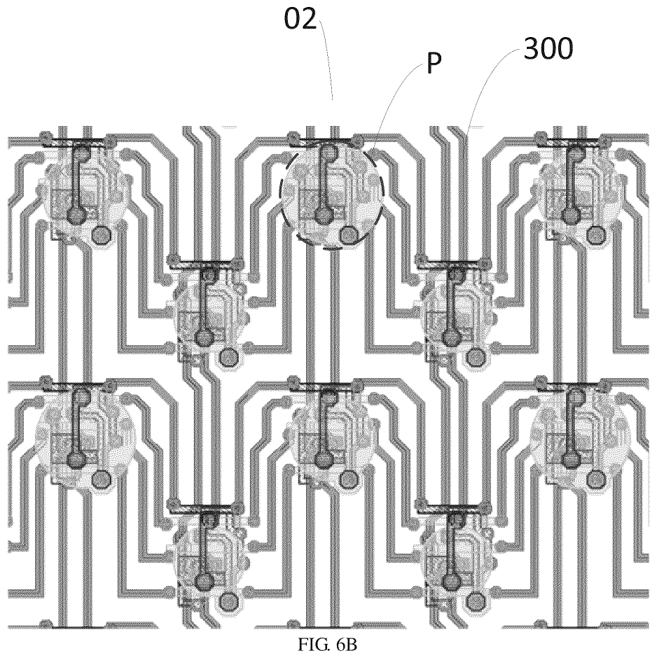

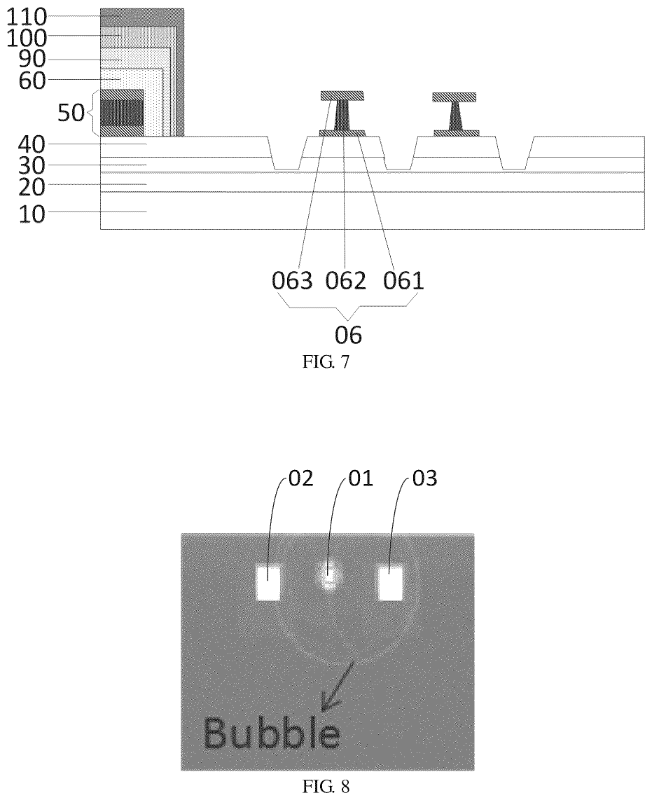

In the related art, the structure of the spacer of the conventional AA Hole product is as shown in FIGS. 4 and 5, and FIGS. 4 and 5 are schematic cross-sectional views along the CC' direction in FIG. 1. The product includes a base substrate 10, and inorganic film layers 20 (a barrier layer +a buffer layer), gate insulating layers 30 (e.g., a first gate insulating layer, a second gate insulating layer and a third gate insulating layer), an interlayer insulating layer 40, a first source-drain metal layer (not shown), a first planarization layer (not shown) and a second source-drain metal layer 50 (a sandwiched structure of Ti/Al/Ti) and a second planarization layer 60 which are sequentially stacked on the base substrate 10. The spacer 06 adopts the design of the second source-drain metal layer 50, that is, Ti/Al/Ti film layers are evaporated and dry etched to form the spacer 06 and the second source-drain metal layer 50. Only the spacer 06 is shown in the through hole packaging region BB, and the spacer 06 is generally designed as an undercut structure. In FIG. 4, a metal film layer 70 for manufacturing an anode is evaporated on the second planarization layer 60, a first photoresist 80 is coated on the metal film layer 70, the first photoresist 80 is exposed and developed, and the metal film layer 70 is wet etched to form an anode (not shown) in the display region AA, and the metal film layer 70 in other regions is removed. Because the wet etching solution of the metal film layer 70 is dilute acid, during the etching process, Al in the spacer 06 (a sandwiched structure of Ti/Al/Ti) is etched to form the spacer 06 with an undercut structure. As shown in FIG. 5, the bottom Ti layer is denoted by 061, the Al layer is denoted by 062, and the top Ti layer is denoted by 063. The structures in FIGS. 4 and 5 are spacers 06 manufactured for the display screen which does not adopt TOF face unlocking design at present. However, for the display screen which adopts TOF face unlocking design, that is, “under display TOF+AA hole” technology, light-emitting devices are retained to emit light in the receiving hole 02 and the transmitting hole 03 of the under display TOF technology, the driving circuits for driving the light-emitting devices to emit light are moved to the display region AA or the frame region, the driving circuit is electrically connected to the anode of the light-emitting device through a transparent wire (e.g., ITO), and the transparent wire is located between the anode and the second source-drain layer. In order to avoid transparent wires occupying space, multiple layers of transparent wires are generally used, as shown in FIG. 6A. For example, three layers of transparent wires (not shown in FIG. 6A) located between the second planarization layer 60 and the metal film layer 70 are included, and planarization layers (e.g., the third planarization layer 90, the fourth planarization layer 100 and the fifth planarization layer 110) are respectively arranged between the film layers where the transparent wires are located. As shown in FIG. 6B, which is a schematic diagram of the pixel arrangement of the transmitting hole 02 in FIG. 1, a plurality of pixel units P are included in the transmitting hole 02, each pixel unit P includes a light-emitting device, the light-emitting device includes an anode, a light-emitting layer and a cathode which are stacked; the driving circuit for driving the light-emitting device in the pixel unit P is moved to the display region AA or the frame region, and the anode of the light-emitting device is electrically connected with the peripheral driving circuit through a transparent wire 300. FIG. 6B merely illustrates one layer of transparent wires, and of course, in order to save wiring space, it is not limited to one layer of transparent wires. There may be two layers or three layers of transparent wires, and so on. However, the transparent wire used to improve the transmittance can only be formed by wet etching at present, and the wet etching solution is similar to the anode wet etching solution, and both use dilute acid. Therefore, the etching solution used in the formation process of the transparent wire will inevitably corrode Al in the spacer 06 (a sandwiched structure of Ti/Al/Ti), resulting in severe corrosion on the spacer 06 (as shown in FIG. 7) and formation of bubbles at the position of the AA hole (as shown in FIG. 8) in the formation process of the transparent wire and a subsequent process (anodic etching). Thus, it is difficult to carry out the design scheme of the under display camera in combination with the spacer of AA Hole.

In order to solve the defective problems of severe corrosion on the spacer and formation of bubbles at the position of AA Hole during the etching process of the transparent wires in the “under display TOF+AA hole” technology, an embodiment of the present disclosure provides a display panel. As shown in FIGS. 1, 3, 12, 15, 17 and 18, FIGS. 12, 15, 17 and 18 are respectively cross-sectional views along the CC′ direction in FIG. 1, and only spacers are illustrated in the through hole packaging region. The display panel includes:
a base substrate 10, wherein the display panel is provided with a through hole 01 penetrating through the base substrate 10 along a thickness direction of the base substrate 10, and the base substrate 10 is provided with a display region AA and a through hole packaging region BB located between the display region AA and the through hole 01;
a first source-drain metal layer 11, located at a side of the base substrate;
a second source-drain metal layer 50, located at a side of the first source-drain metal layer 11 away from the base substrate 10;
at least one spacer 06, wherein two spacers 06 are taken as an example in the present disclosure, and the spacers 06 are located at a side of the base substrate 10, located in the through hole packaging region BB, and arranged around the through hole 01; the spacers 06 are disposed in a different layer from the second source-drain metal layer 50.

In the display panel provided by the embodiment of the present disclosure, the spacer 06 is arranged in a different layer from the second source-drain metal layer 50, that is, the spacer 06 and the second source-drain metal layer 50 are located in different layers. Thus, the spacer 06 can be arranged in the same layer as the first source-drain metal layer 11; then, a passivation layer can be deposited on a side of the first source-drain metal layer 11 away from the base substrate 10 to protect the spacer 06; and then, subsequent processes, such as etching of multiple layers of transparent wires in the under display TOF technology, can be performed, and the arrangement of the passivation layer can avoid the problem of severe corrosion of the Al layer of the spacer during the etching process of the transparent wire. After the etching of the transparent wire is completed, the passivation layer for protecting the spacer 06 is removed. And then, the anodic etching is performed, and the Al layer in the spacer 06 is etched during the anodic etching process, thereby forming the spacer with an undercut structure. In addition, the spacer 06 can also be arranged in the same layer as a film layer (e.g., a third source-drain metal layer, etc.) located at a side of the second source-drain metal layer 50 away from the base substrate 10, and the third source-drain metal layer is disposed at a side of the multiple layers of transparent wires away from the base substrate 10; that is, after the etching of the transparent wires is completed, the spacer 06 is manufactured at the same time as the third source-drain metal layer, thus avoiding the problem of severe corrosion on the Al layer of the spacer in the etching process of the transparent wires. And then, the anodic etching is performed, and the Al layer in the spacer 06 is etched during the anodic etching process, thereby forming the spacer with an undercut structure. Therefore, the display panel provided by the embodiment of the present disclosure can avoid the defective problems of severe corrosion on the spacer 06 and formation of bubbles at the position of AA Hole during the etching process of the transparent wires in the “under display TOF+AA hole” technology.

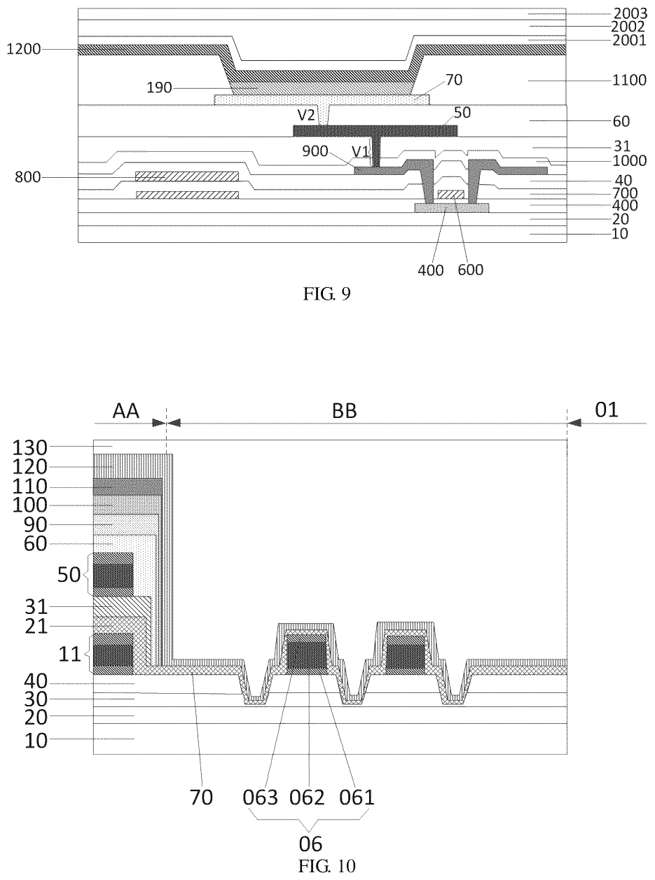

As shown in FIG. 9, FIG. 9 is a cross-sectional view of one pixel in the display region AA in FIG. 1. the display panel includes a barrier layer, a buffer layer (the barrier layer and the buffer layer are represented by the inorganic film layer 20 as described above), an active layer 400, a first gate insulating layer 500, a first gate electrode layer 600, a second gate insulating layer 700, a second gate electrode layer 800, an interlayer insulating layer 40, a first source-drain metal layer 900, a passivation layer 1000, a first planarization layer 31, a second source-drain metal layer 50, a second planarization layer 60, an anode 70, a pixel defining layer 1100, a light-emitting layer 190, a cathode 1200, a first inorganic layer 2001, an organic layer 2002 and a second inorganic layer 2003, which are sequentially stacked on the base substrate 10. The first inorganic layer 2001, the organic layer 2002 and the second inorganic layer 2003 form an encapsulation layer 200; the first source-drain metal layer 900 and the second source-drain metal layer 50 are electrically connected through a first via V1 penetrating the first planarization layer 31 and the passivation layer 1000, and the anode 70 is electrically connected with the second source-drain metal layer 50 through a second via V2 penetrating the second planarization layer 60.

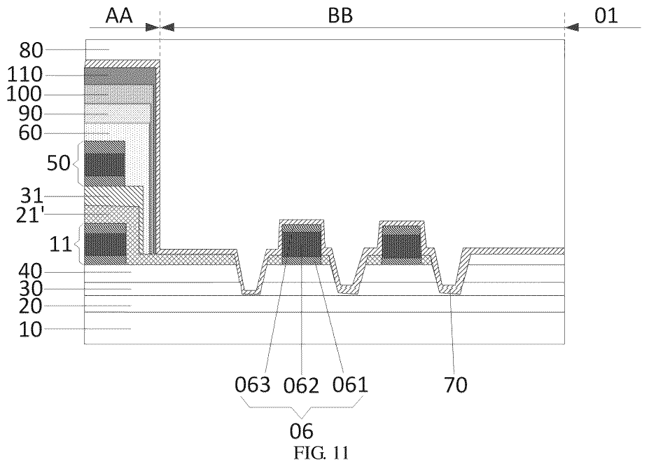

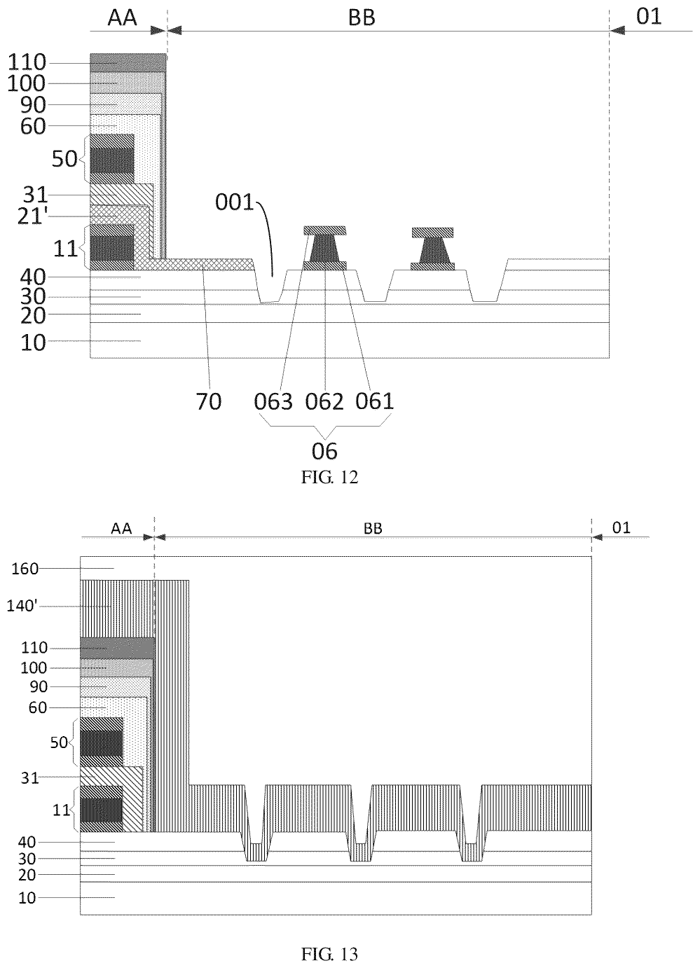

In specific implementation, in the display panel provided by the embodiment of the present invention, as shown in FIG. 12, the spacer 06 is disposed in the same layer and made of the same material as at least one film layer located between the base substrate 10 and the second source-drain metal layer 50. Specifically, the spacer 06 can be disposed in the same layer and made of the same material as the first source-drain metal layer 11. In the specific manufacturing process, as shown in FIG. 10, an inorganic film layer 20 (barrier layer+buffer layer), a gate insulating layer 30 (e.g., a first gate insulating layer, a second gate insulating layer and a third gate insulating layer) and an interlayer insulating layer 40 are sequentially manufactured on the base substrate 10; a Ti/Al/Ti metal film layer is deposited on the interlayer insulating layer 40, and a first source-drain metal layer 11 located in the display region AA and an spacer 06 located in the through hole packaging region BB are formed by one patterning process. Then, a first passivation film layer 21 is deposited at a side of the first source-drain metal layer 11 away from the base substrate 10, and the first passivation film layer 21 covers the through hole packaging region BB to protect the spacer; next, a first planarization layer 31 is formed at a side of the first passivation film layer 21 away from the base substrate 10, and an orthographic projection of the first planarization layer 31 on the base substrate 10 does not overlap with an orthographic projection of the spacer 06 on the base substrate 10; then, a second source-drain metal layer 50 is formed at a side of the first planarization layer 31 away from the base substrate 10; next, a second planarization layer 60 is formed at a side of the second source-drain metal layer 50 away from the base substrate 10; and then multiple layers of transparent wires (not shown) are formed at a side of the second planarization layer 60 away from the base substrate 10. The transparent wires in the multiple layers of transparent wires are used to electrically connect the anodes of the light-emitting devices disposed in the receiving hole 02 and the transmitting hole 03 in FIG. 1 with the peripheral driving circuits (for example, located in the display region or the frame region). Taking three layers of transparent wires as an example, there is a planarization layer between two adjacent layers of transparent wires. FIG. 10 illustrates a third planarization layer 90, a fourth planarization layer 100 and a fifth planarization layer 110 which are sequentially stacked at a side of the second planarization layer 60 away from the base substrate 10. The orthographic projection of each of the second planarization layer 60, the third planarization layer 90, the fourth planarization layer 100 and the fifth planarization layer 110 on the base substrate 10 does not overlap with the orthographic projection of the spacer 06 on the base substrate 10. There is one layer of transparent wires between the second planarization layer 60 and the third planarization layer 90, there is one layer of transparent wires between the third planarization layer 90 and the fourth planarization layer 100, and there is one layer of transparent wires between the fourth planarization layer 100 and the fifth planarization layer 110. An orthographic projection of the transparent wires on the base substrate 10 does not overlap with the orthographic projection of the spacer 06 on the base substrate 10. Next, a second passivation film layer 120 is deposited at a side of the fifth planarization layer 110 away from the base substrate 10. And then, a second photoresist 130 is coated on a side of the second passivation film layer 120 away from the base substrate 10, the second photoresist 130 is exposed and developed, and the first passivation film layer 21 and the second passivation film layer 120 are etched. As shown in FIG. 11, a first passivation layer 21′ is formed, the first passivation layer 21′ covers the through hole packaging region BB, an orthographic projection of the first passivation layer 21′ on the base substrate 10 does not overlap with the orthographic projection of the spacer 06 on the base substrate 10, and the second passivation film layer 120 is completely removed. Next, a metal film layer 70 for manufacturing an anode is evaporated on a side of the fifth planarization layer 110 away from the base substrate 10, a first photoresist 80 is coated on the metal film layer 70, the first photoresist 80 is exposed and developed, and the metal film layer 70 is wet etched to form an anode (not shown) in the display region AA, and the metal film layer 70 in other regions is removed, that is, an orthographic projection of the anode on the base substrate 10 does not overlap with the orthographic projection of the spacer 06 on the base substrate 10. Because the wet etching solution of the metal film layer 70 is dilute acid, during the etching process, Al in the spacer 06 (a sandwiched structure of Ti/Al/Ti) is etched to form the spacer 06 with an undercut structure. As shown in FIG. 12, the bottom Ti layer is denoted by 061, the Al layer is denoted by 062, and the top Ti layer is denoted by 063. Therefore, in the scheme shown in FIGS. 10-12, the arrangement of the first passivation film layer 21 can avoid the problem of severe corrosion of the Al layer of the spacer during the etching process of the transparent wires. After the etching of the transparent wires is completed, the passivation layer for protecting the spacer 06 is removed. And then, the anodic etching is performed, and the Al layer in the spacer 06 is etched during the anodic etching process, thereby forming the spacer 06 with an undercut structure.

It should be noted that, as shown in FIG. 11, it is taken as an example that the fifth planarization layer 110 is formed and the second passivation film layer 120 is completely removed. Of course, the fifth planarization layer 110 may not be provided, and the second passivation film layer 120 is directly formed instead of the fifth planarization layer 110; and the second passivation film layer 120 may be retained at the position corresponding to the display region AA and be removed at the position corresponding to the through hole packaging region BB. In addition, in FIG. 11, the first passivation film layer 21 is etched by providing a second passivation film layer 120. Of course, the second passivation film layer 120 may not be provided, and after the fifth planarization layer 110 is formed, the first passivation film layer 21 is directly etched.

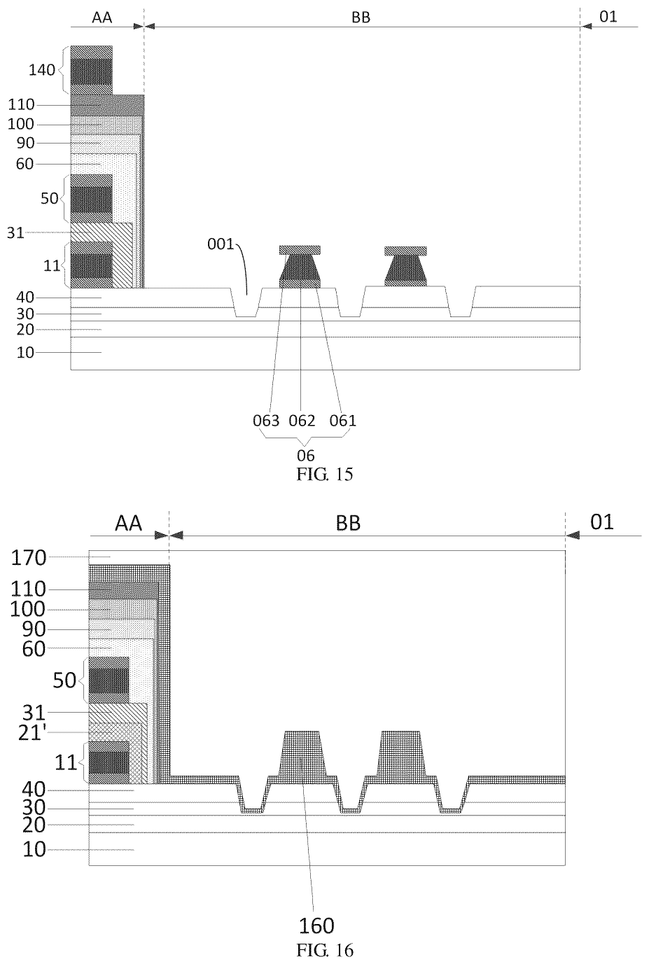

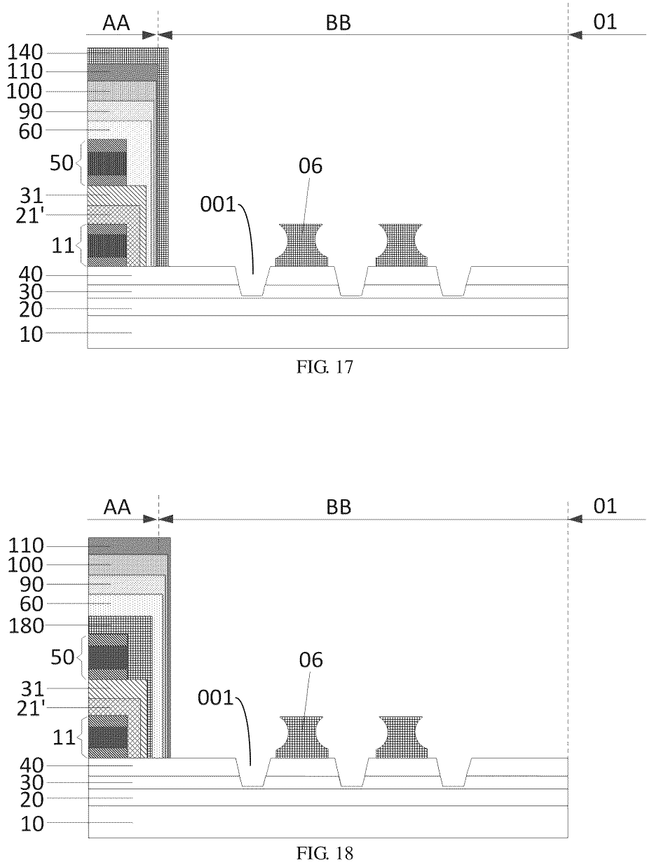

In specific implementation, as shown in FIGS. 15 and 17, the display panel provided by the embodiment of the present invention further includes: at least one transparent wiring layer (not shown) located at a side of the second source-drain metal layer 50 away from the base substrate 10, an anode (not shown) located at a side of the transparent wiring layer away from the base substrate 10, and a first film layer 140 located between the transparent wiring layer and the anode. The orthographic projection of the transparent wiring layer on the base substrate 10 does not overlap with the orthographic projection of the spacer 06 on the base substrate 10, and the orthographic projection of the anode on the base substrate 10 does not overlap with the orthographic projection of the spacer 06 on the base substrate 10;
the spacer 06 is disposed in the same layer and made of the same material as the first film layer 140.

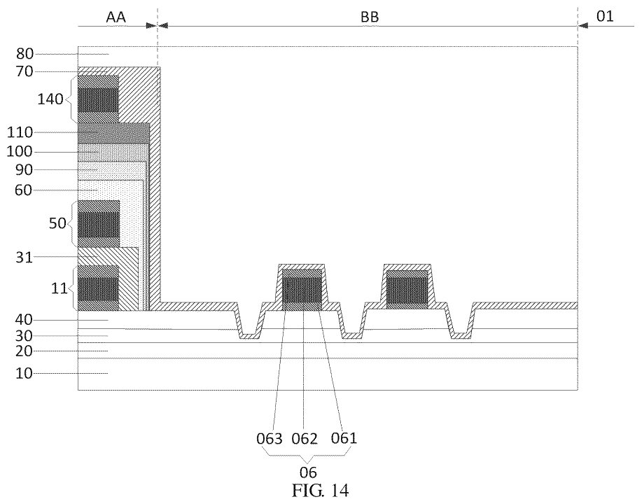

In specific implementation, in the display panel provided by the embodiment of the present invention, as shown in FIG. 15, the material of the first film layer 140 is the same as the material of the first source-drain metal layer 11, that is, the material of the first film layer 140 is Ti/Al/Ti. In the specific manufacturing process, as shown in FIG. 13, inorganic film layers 20 (barrier layer +buffer layer), gate insulating layers 30 (e.g., a first gate insulating layer, a second gate insulating layer and a third gate insulating layer) and an interlayer insulating layer 40 are sequentially manufactured on the base substrate 10; a Ti/Al/Ti metal film layer is deposited on the interlayer insulating layer 40, and a first source-drain metal layer 11 located in the display region AA is formed by a patterning process. Next, a first planarization layer 31 is formed at a side of the first source-drain metal layer 11 away from the base substrate 10, and the orthographic projection of the first planarization layer 31 on the base substrate 10 does not overlap with the orthographic projection of the spacer 06 on the base substrate 10; then, a second source-drain metal layer 50 is formed at a side of the first planarization layer 31 away from the base substrate 10; next, a second planarization layer 60 is formed at a side of the second source-drain metal layer 50 away from the base substrate 10; and then multiple layers of transparent wires (not shown) are formed at a side of the second planarization layer 60 away from the base substrate 10. The transparent wires in the multiple layers of transparent wires are used to electrically connect the anodes of the light-emitting devices disposed in the receiving hole 02 and the transmitting hole 03 in FIG. 1 with the peripheral driving circuits (for example, located in the display region or the frame region). Taking three layers of transparent wires as an example, there is a planarization layer between two adjacent layers of transparent wires. FIG. 10 illustrates a third planarization layer 90, a fourth planarization layer 100 and a fifth planarization layer 110 which are sequentially stacked at a side of the second planarization layer 60 away from the base substrate 10. The orthographic projection of each of the second planarization layer 60, the third planarization layer 90, the fourth planarization layer 100 and the fifth planarization layer 110 on the base substrate 10 does not overlap with the orthographic projection of the spacer 06 on the base substrate 10. There is one layer of transparent wires between the second planarization layer 60 and the third planarization layer 90, there is one layer of transparent wires between the third planarization layer 90 and the fourth planarization layer 100, and there is one layer of transparent wires between the fourth planarization layer 100 and the fifth planarization layer 110. The orthographic projection of the transparent wire on the base substrate 10 does not overlap with the orthographic projection of the spacer 06 on the base substrate 10. Next, a first material film layer (Ti/Al/Ti) 140′ is deposited at a side of the fifth planarization layer 110 away from the base substrate 10, a third photoresist 150 is coated on a side of the first material film layer 140′ away from the base substrate 10, the third photoresist 150 is exposed and developed, and the first material film layer 140′ is etched, as shown in FIG. 14, to form a first film layer 140 in the AA region and a spacer 06 in the through hole packaging region BB. Then, a metal film layer 70 for manufacturing an anode is evaporated on a side of the first film layer 140 away from the base substrate 10, a first photoresist 80 is coated on the metal film layer 70, the first photoresist 80 is exposed and developed, and the metal film layer 70 is wet etched to form an anode (not shown) in the display region AA, and the metal film layer 70 in other regions is removed, that is, the orthographic projection of the anode on the base substrate 10 does not overlap with the orthographic projection of the spacer 06 on the base substrate 10. Because the wet etching solution of the metal film layer 70 is dilute acid, during the etching process, Al in the spacer 06 (a sandwiched structure of Ti/Al/Ti) is etched to form the spacer 06 with an undercut structure. As shown in FIG. 15, the bottom Ti layer is denoted by 061, the Al layer is denoted by 062, and the top Ti layer is denoted by 063. Therefore, in the scheme shown in FIGS. 13-15, after the transparent wires are manufactured, a first film layer 140 made of the same material as the first source-drain metal 11 is manufactured, and the spacer 06 is disposed in the same layer as the first film layer 140, thus avoiding the problem of severe corrosion of the Al layer of the spacer during the etching process of the transparent wires.

Specifically, as shown in FIG. 6B, the anodes of the light emitting devices in the transmitting hole 02 and the receiving hole 03 in FIG. 1 provided by the embodiment of the present disclosure are electrically connected with the peripheral driving circuits through transparent wires 300, and only one layer of transparent wires 300 is shown in FIG. 6B. Of course, there may be 2 layers, 3 layers or even more layers. In the case where the transparent wiring layers are 2 layers, 3 layers or even more layers, one planarization layer (the third planarization layer 90, the fourth planarization layer 100 or the fifth planarization layer 110) is disposed between two adjacent layers of transparent wires 300.

In specific implementation, in the display panel provided by the embodiment of the present invention, as shown in FIG. 17, the material of the first film layer 140 is negative photoresist. The manufacturing process of the spacer 06 in FIG. 17 is different from the manufacturing process of the spacer 06 in FIG. 15 in that, as shown in FIG. 16, there is a first passivation layer 21′ between the first planarization layer 31 and the first source-drain metal layer 11, the first passivation layer 21′ covers the through hole packaging region BB, and the orthographic projection of the first passivation layer 21′ on the base substrate 10 does not overlap with the orthographic projection of the spacer 06 on the base substrate 10; after the fifth planarization layer 10 is formed, a second material film layer 160 made of negative photoresist is coated on a side of the fifth planarization layer 110 away from the base substrate 10, a fourth photoresist 170 is coated on a side of the second material film layer 160 away from the base substrate 10, the fourth photoresist 170 is exposed and developed, and by controlling the exposure and development conditions, as shown in FIG. 17, a first film layer 140 made of negative photoresist is formed in the AA region and an spacer 06 with an undercut structure is formed in the through hole packaging region BB. The subsequent manufacturing process of the anode based on FIG. 17 is the same as that based on FIG. 15, and details will not be repeated here. Therefore, in the scheme shown in FIGS. 16-17, after the transparent wires are manufactured, the first film layer 140 made of negative photoresist is further manufactured, and the spacer 06 is disposed in the same layer as the first film layer 140, thus avoiding the problem of severe corrosion of the Al layer of the spacer during the etching process of the transparent wires.

In specific implementation, as shown in FIG. 18, the display panel provided by the embodiment of the present invention further includes: at least one transparent wiring layer (not shown) located at a side of the second source-drain metal layer 50 away from the base substrate 10, an anode (not shown) located at a side of the transparent wiring layer away from the base substrate 10, a second planarization layer 60 located between the transparent wiring layer and the second source-drain metal layer 50, and a negative photoresist layer 180 between the second source-drain metal layer 50 and the second planarization layer 60; and further includes: a first passivation layer 21′ located between the first planarization layer 31 and the first source-drain metal layer 11. The first passivation layer 21′ covers the through hole packaging region BB, and the orthographic projection of the first passivation layer 21′ on the base substrate 10 does not overlap with the orthographic projection of the spacer 06 on the base substrate 10; the orthographic projection of the transparent wiring layer on the base substrate 10 does not overlap with the orthographic projection of the spacer 06 on the base substrate 10, and the orthographic projection of the anode on the base substrate does not overlap with the orthographic projection of the spacer 06 on the base substrate 10;
the spacer 06 is disposed in the same layer and made of the same material as the negative photoresist layer 180.

In specific implementation, in the display panel provided by the embodiment of the present invention, as shown in FIG. 18, after the second source-drain metal layer 50 is formed, a negative photoresist material film layer is coated on a side of the second source-drain metal layer 50 away from the base substrate 10, a fifth photoresist is coated on a side of the negative photoresist material film layer away from the base substrate 10, the fifth photoresist is exposed and developed, and by controlling the exposure and development conditions, as shown in FIG. 18, a negative photoresist layer 180 is formed in the AA region and an spacer 06 with an undercut structure is formed in the through hole packaging region BB. And then, the subsequent manufacturing processes of the transparent wires and the anode are performed, and the structure in FIG. 18 can also avoid the problem of severe corrosion of the Al layer of the spacer during the etching process of the transparent wires.

It should be noted that the first film layer 140 formed in the AA region in FIG. 15 can be used for arrangement of wires (such as data lines, etc.), which can reduce the occupied area of the wires; the first film layer 140 formed in the AA region in FIG. 17 can play a planarization role, and the negative photoresist layer 180 formed in the AA region in FIG. 18 can play a planarization role.

Specifically, as shown in FIGS. 12, 15, 17 and 18, the number of spacers 06 is generally set to be more than three, or the number of spacers 06 can be reduced to two. After the number of spacers 06 is reduced, the material of the organic layer in the encapsulation layer will overflow during inkjet printing, and therefore, isolation grooves 001 are arranged around the spacers, and one or two isolation grooves 001 can be added between two spacers 06. Of course, the isolation groove 001 may not be provided. Specifically, the base substrate 10 can include a first flexible substrate, a first barrier layer and a second flexible substrate which are stacked; the second flexible substrate is close to the barrier layer and buffer layer 20, and the isolation groove 001 can be formed by penetrating the following film layers: the interlayer insulating layer 40, the second gate insulating layer 700, the first gate insulating layer 500, the barrier layer and buffer layer 20, the second flexible substrate, the first barrier layer and part of the first flexible substrate. Of course, it is not limited thereto, and the film layers being penetrated can be selected according to actual needs, so as to form the isolation groove 001.

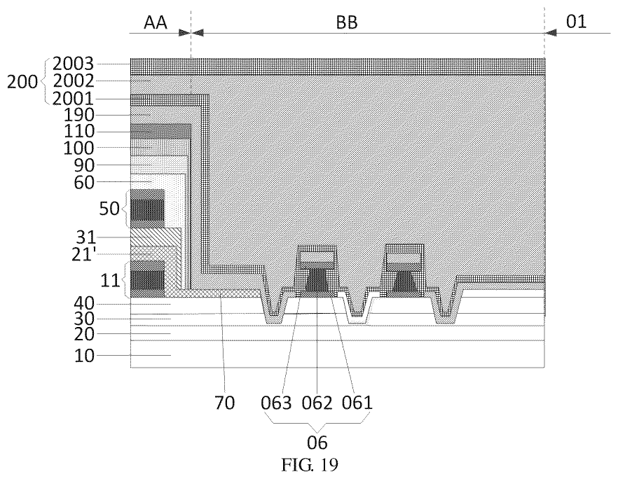

In specific implementation, as shown in FIG. 19, the display panel provided by the embodiment of the present invention further includes: a light-emitting layer 190 located at a side of the anode away from the base substrate 10, a cathode (not shown) located at a side of the light-emitting layer 190 away from the base substrate 10, and an encapsulation layer 200 located at a side of the cathode away from the base substrate 10. The light-emitting layer 190 is disconnected at the position of the spacer 06;
the encapsulation layer 200 includes a first inorganic layer 2001, an organic layer 2002 and a second inorganic layer 2003 which are stacked, an orthographic projection of each of the first inorganic layer 2001, the organic layer 2002 and the second inorganic layer 2003 on the base substrate 10 covers the display region AA and the through hole packaging region BB.

In specific implementation, the display panel provided by the embodiment of the present disclosure can further include other functional film layers well known to those skilled in the art, such as an active layer, a first gate electrode layer, a second gate electrode layer, a third gate electrode layer, and a touch layer and a cover plate which are located at a side of the encapsulation layer away from the base substrate, etc.

Based on the same inventive concept, an embodiment of the present disclosure further provides a manufacturing method for manufacturing the above display panel, which includes:
providing a base substrate, wherein the base substrate is provided with a display region, a through hole region, and a through hole packaging region located between the display region and the through hole region;
forming a first source-drain metal layer at a side of the display region of the base substrate;
forming a second source-drain metal layer at a side of the first source-drain metal layer away from the base substrate;
forming at least one spacer at a side of the through hole packaging region of the base substrate and arranged around the through hole region, wherein the at least one spacer is disposed in a different layer from the second source-drain metal layer;
cutting the through hole region to form a through hole.

In specific implementation, in the manufacturing method provided by the embodiment of the present invention, the forming the at least one spacer at a side of the through hole packaging region of the base substrate and arranged around the through hole region, specifically includes:
forming the first source-drain metal layer in the display region and the at least one spacer in the through hole packaging region by one patterning process.

In specific implementation, in the manufacturing method provided by the embodiment of the present invention, after forming the first source-drain metal layer and before forming the second source-drain metal layer, the manufacturing method further includes: forming a first passivation film layer and a first planarization film layer, and patterning the first planarization film layer to form a first planarization layer, wherein the orthographic projection of the first planarization layer on the base substrate does not overlap with the orthographic projection of the at least one spacer on the base substrate;
after forming the second source-drain metal layer, the manufacturing method further includes:
forming at least one transparent wiring layer, wherein the orthographic projection of the at least one transparent wiring layer on the base substrate does not overlap with the orthographic projection of the at least one spacer on the base substrate;
forming a second passivation film layer at a side of the transparent wiring layer away from the base substrate;
patterning the first passivation film layer and the second passivation film layer by one patterning process, so as to form a first passivation layer and completely remove the second passivation film layer, wherein the first passivation layer covers the through hole packaging region, and the orthographic projection of the first passivation layer on the base substrate does not overlap with the orthographic projection of the at least one spacer on the base substrate; or, patterning the first passivation film layer and the second passivation film layer by one patterning process, so as to form a first passivation layer and a second passivation layer, wherein the first passivation layer covers the through hole packaging region, the orthographic projection of the first passivation layer on the base substrate does not overlap with the orthographic projection of the at least one spacer on the base substrate, and the orthographic projection of the second passivation layer on the base substrate does not overlap with the orthographic projection of the at least one spacer on the base substrate.

In specific implementation, in the manufacturing method provided by the embodiment of the present invention, after forming the first source-drain metal layer and before forming the second source-drain metal layer, the manufacturing method further includes: forming a first planarization layer, wherein the orthographic projection of the first planarization layer on the base substrate does not overlap with the orthographic projection of the at least one spacer on the base substrate;
after forming the second source-drain metal layer, the manufacturing method further includes: forming at least one transparent wiring layer, wherein an orthographic projection of the at least one transparent wiring layer on the base substrate does not overlap with the orthographic projection of the at least one spacer on the base substrate;
the forming the at least one spacer at a side of the through hole packaging region of the base substrate and arranged around the through hole region, specifically includes:
forming a first material film layer made of the same material as the first source-drain metal layer at a side of the at least one transparent wiring layer away from the base substrate;
patterning the first material film layer to form a first film layer located in the display region and the at least one spacer located in the through hole packaging region.

In specific implementation, in the manufacturing method provided by the embodiment of the present invention, after forming the first source-drain metal layer and before forming the second source-drain metal layer, the manufacturing method further includes: forming a first passivation layer and a first planarization layer, wherein the orthographic projection of the first passivation layer on the base substrate does not overlap with the orthographic projection of the at least one spacer on the base substrate, and the orthographic projection of the first planarization layer on the base substrate does not overlap with the orthographic projection of the at least one spacer on the base substrate;
after forming the second source-drain metal layer, the manufacturing method further includes: forming at least one transparent wiring layer, wherein the orthographic projection of the at least one transparent wiring layer on the base substrate does not overlap with the orthographic projection of the at least one spacer on the base substrate;
the forming the at least one spacer at a side of the through hole packaging region of the base substrate and arranged around the through hole region, specifically includes:
forming a second material film layer made of negative photoresist at a side of the at least one transparent wiring layer away from the base substrate;
patterning the second material film layer to form a first film layer located in the display region and the at least one spacer located in the through hole packaging region.

It should be noted that the manufacturing method of the display panel provided by the embodiment of the present disclosure can refer to the manufacturing process of the display panel in the embodiments of the display panel as mentioned above, and details will not be repeated here.

Based on the same inventive concept, an embodiment of the present disclosure further provides a display device, which includes any of the display panels provided by the embodiments of the present disclosure as mentioned above. The display device can be any product or component having display function, such as a mobile phone, a tablet computer, a television, a display, a notebook computer, a digital photo frame, a navigator, etc. The implementation of the display device can refer to the embodiments of the display panel, and details will not be repeated here.

In the display panel, the manufacturing method therefor and the display device provided by the embodiments of the present disclosure, the spacer is arranged in a different layer from the second source-drain metal layer, that is, the spacer and the second source-drain metal layer are located in different layers. Thus, the spacer can be arranged in the same layer as the first source-drain metal layer; then, a passivation layer can be deposited on a side of the first source-drain metal layer away from the base substrate to protect the spacer; and then, subsequent processes, such as etching of multiple layers of transparent wires in the under display TOF technology, can be performed, and the arrangement of the passivation layer can avoid the problem of severe corrosion of the Al layer of the spacer during the etching process of the transparent wire. After the etching of the transparent wire is completed, the passivation layer for protecting the spacer is removed. And then, the anodic etching is performed, and the Al layer in the spacer is etched during the anodic etching process, thereby forming the spacer with an undercut structure. In addition, the spacer can also be arranged in the same layer as a film layer (e.g., a third source-drain metal layer, etc.) located at a side of the second source-drain metal layer away from the base substrate, and the third source-drain metal layer is disposed at a side of the multiple layers of transparent wires away from the base substrate; that is, after the etching of the transparent wires is completed, the spacer is manufactured at the same time as the third source-drain metal layer, thus avoiding the problem of severe corrosion on the Al layer of the spacer in the etching process of the transparent wires. And then, the anodic etching is performed, and the Al layer in the spacer is etched during the anodic etching process, thereby forming the spacer with an undercut structure. Therefore, the display panel provided by the embodiment of the present disclosure can avoid the defective problems of severe corrosion on the spacer and formation of bubbles at the position of AA Hole during the etching process of the transparent wires in the “under display TOF+AA hole” technology.

Obviously, those skilled in the art can make various modifications and variations to the present disclosure without departing from its spirit and scope. Thus, if these modifications and variations of the present disclosure are within the scope of the claims of the present disclosure and their equivalents, the present disclosure is also intended to include these modifications and variations.

1. A display panel, comprising:
a base substrate, wherein the display panel is provided with a through hole penetrating through the base substrate along a thickness direction of the base substrate, and the base substrate is provided with a display region and a through hole packaging region located between the display region and the through hole;
a first source-drain metal layer, located at a side of the base substrate;
a second source-drain metal layer, located at a side of the first source-drain metal layer away from the base substrate;
at least one spacer, located at a side of the base substrate, located in the through hole packaging region and arranged around the through hole; wherein the at least one spacer is disposed in a different layer from the second source-drain metal layer.

2. The display panel according to claim 1, wherein the at least one spacer is disposed in the same layer and made of the same material as at least one film layer located between the base substrate and the second source-drain metal layer.

3. The display panel according to claim 2, wherein the at least one spacer is disposed in the same layer and made of the same material as the first source-drain metal layer.

4. The display panel according to claim 3, further comprising: at least one transparent wiring layer located at a side of the second source-drain metal layer away from the base substrate, and an anode located at a side of the at least one transparent wiring layer away from the base substrate; wherein an orthographic projection of the at least one transparent wiring layer on the base substrate does not overlap with an orthographic projection of the at least one spacer on the base substrate, and an orthographic projection of the anode on the base substrate does not overlap with the orthographic projection of the at least one spacer on the base substrate.

5. The display panel according to claim 4, further comprising: a first passivation layer located between the second source-drain metal layer and the first source-drain metal layer, and a first planarization layer between the first passivation layer and the second source-drain metal layer; wherein an orthographic projection of the first planarization layer on the base substrate does not overlap with the orthographic projection of the at least one spacer on the base substrate, the first passivation layer covers the through hole packaging region, and an orthographic projection of the first passivation layer on the base substrate does not overlap with the orthographic projection of the at least one spacer on the base substrate.

6. The display panel according to claim 5, further comprising: a second passivation layer located between the at least one transparent wiring layer and the anode, wherein an orthographic projection of the second passivation layer on the base substrate does not overlap with the orthographic projection of the at least one spacer on the base substrate.

7. The display panel according to claim 1, further comprising: at least one transparent wiring layer located at a side of the second source-drain metal layer away from the base substrate, an anode located at a side of the at least one transparent wiring layer away from the base substrate, and a first film layer located between the at least one transparent wiring layer and the anode; wherein an orthographic projection of the at least one transparent wiring layer on the base substrate does not overlap with an orthographic projection of the at least one spacer on the base substrate, and an orthographic projection of the anode on the base substrate does not overlap with the orthographic projection of the at least one spacer on the base substrate;
the at least one spacer is disposed in the same layer and made of the same material as the first film layer.

8. The display panel according to claim 7, wherein a material of the first film layer is the same as a material of the first source-drain metal layer, or a material of the first film layer is negative photoresist.

9. The display panel according to claim 1, further comprising: at least one transparent wiring layer located at a side of the second source-drain metal layer away from the base substrate, an anode located at a side of the at least one transparent wiring layer away from the base substrate, a second planarization layer located between the at least one transparent wiring layer and the second source-drain metal layer, and a negative photoresist layer located between the second source-drain metal layer and the second planarization layer; wherein an orthographic projection of the at least one transparent wiring layer on the base substrate does not overlap with an orthographic projection of the at least one spacer on the base substrate, and an orthographic projection of the anode on the base substrate does not overlap with the orthographic projection of the at least one spacer on the base substrate;
the at least one spacer is disposed in the same layer and made of the same material as the negative photoresist layer.

10. The display panel according to claim 7, further comprising: a first planarization layer located between the first source-drain metal layer and the second source-drain metal layer.

11. The display panel according to claim 8, wherein in a case where a material of the at least one spacer is negative photoresist, the display panel further comprises a first passivation layer located between the first planarization layer and the first source-drain metal layer, the first passivation layer covers the through hole packaging region, and an orthographic projection of the first passivation layer on the base substrate does not overlap with the orthographic projection of the at least one spacer on the base substrate.

12. The display panel according to claim 4, further comprising: a light-emitting layer located at a side of the anode away from the base substrate, a cathode located at a side of the light-emitting layer away from the base substrate, and an encapsulation layer located at a side of the cathode away from the base substrate; wherein the light-emitting layer is disconnected at a position of the at least one spacer;
the encapsulation layer comprises a first inorganic layer, an organic layer and a second inorganic layer which are stacked, wherein an orthographic projection of each of the first inorganic layer, the organic layer and the second inorganic layer on the base substrate covers the display region and the through hole packaging region.

13. A display device, comprising the display panel according to claim 1.

14. A manufacturing method for manufacturing the display panel according to claim 1, comprising:
providing a base substrate, wherein the base substrate is provided with a display region, a through hole region, and a through hole packaging region located between the display region and the through hole region;
forming a first source-drain metal layer at a side of the base substrate;
forming a second source-drain metal layer at a side of the first source-drain metal layer away from the base substrate;
forming at least one spacer in the through hole packaging region of the base substrate and arranged around the through hole region, wherein the at least one spacer is disposed in a different layer from the second source-drain metal layer;
cutting the through hole region to form a through hole.

15. The manufacturing method according to claim 14, wherein the forming the at least one spacer at a side of the through hole packaging region of the base substrate and arranged around the through hole region, specifically comprises:
forming the first source-drain metal layer in the display region and the at least one spacer in the through hole packaging region by one patterning process.

16. The manufacturing method according to claim 15, wherein after forming the first source-drain metal layer and before forming the second source-drain metal layer, the manufacturing method further comprises: forming a first passivation film layer and a first planarization film layer, and patterning the first planarization film layer to form a first planarization layer, wherein an orthographic projection of the first planarization layer on the base substrate does not overlap with an orthographic projection of the at least one spacer on the base substrate;
after forming the second source-drain metal layer, the manufacturing method further comprises:
forming at least one transparent wiring layer, wherein an orthographic projection of the at least one transparent wiring layer on the base substrate does not overlap with the orthographic projection of the at least one spacer on the base substrate;
forming a second passivation film layer at a side of the transparent wiring layer away from the base substrate;
patterning the first passivation film layer and the second passivation film layer by one patterning process, so as to form a first passivation layer and completely remove the second passivation film layer, wherein the first passivation layer covers the through hole packaging region, and an orthographic projection of the first passivation layer on the base substrate does not overlap with the orthographic projection of the at least one spacer on the base substrate; or, patterning the first passivation film layer and the second passivation film layer by one patterning process, so as to form a first passivation layer and a second passivation layer, wherein the first passivation layer covers the through hole packaging region, an orthographic projection of the first passivation layer on the base substrate does not overlap with the orthographic projection of the at least one spacer on the base substrate, and an orthographic projection of the second passivation layer on the base substrate does not overlap with the orthographic projection of the at least one spacer on the base substrate.

17. The manufacturing method according to claim 14, wherein after forming the first source-drain metal layer and before forming the second source-drain metal layer, the manufacturing method further comprises: forming a first planarization layer, wherein an orthographic projection of the first planarization layer on the base substrate does not overlap with an orthographic projection of the at least one spacer on the base substrate;
after forming the second source-drain metal layer, the manufacturing method further comprises: forming at least one transparent wiring layer, wherein an orthographic projection of the at least one transparent wiring layer on the base substrate does not overlap with the orthographic projection of the at least one spacer on the base substrate;
the forming the at least one spacer at a side of the through hole packaging region of the base substrate and arranged around the through hole region, specifically comprises:
forming a first material film layer made of the same material as the first source-drain metal layer at a side of the at least one transparent wiring layer away from the base substrate;
patterning the first material film layer to form a first film layer located in the display region and the at least one spacer located in the through hole packaging region.

18. The manufacturing method according to claim 14, wherein after forming the first source-drain metal layer and before forming the second source-drain metal layer, the manufacturing method further comprises: forming a first passivation layer and a first planarization layer, wherein an orthographic projection of the first passivation layer on the base substrate does not overlap with an orthographic projection of the at least one spacer on the base substrate, and an orthographic projection of the first planarization layer on the base substrate does not overlap with the orthographic projection of the at least one spacer on the base substrate;
after forming the second source-drain metal layer, the manufacturing method further comprises: forming at least one transparent wiring layer, wherein an orthographic projection of the at least one transparent wiring layer on the base substrate does not overlap with the orthographic projection of the at least one spacer on the base substrate;
the forming the at least one spacer in the through hole packaging region of the base substrate and arranged around the through hole region, specifically comprises:
forming a second material film layer made of negative photoresist at a side of the at least one transparent wiring layer away from the base substrate;
patterning the second material film layer to form a first film layer located in the display region and the at least one spacer located in the through hole packaging region.
